(19) United States
(12) Patent Application Publication
(10) Pub. No.: US 2025/0379152 A1
(43) Pub. Date: Dec. 11, 2025

(54) SEMICONDUCTOR DEVICES AND METHODS FOR FORMING THE SAME

(71) Applicant: Yangtze Memory Technologies Co., Ltd., Wuhan (CN)

(72) Inventors: Wenbo ZHANG, Wuhan (CN); Kai YU, Wuhan (CN); Zhiyong LU, Wuhan (CN); Sijia WU, Wuhan (CN); Sheng PENG, Wuhan (CN); Zhaohui CHENG, Wuhan (CN); Zhangyi LI, Wuhan (CN); Jing GAO, Wuhan (CN)

(21) Appl. No.: 18/791,391

(22) Filed: Jul. 31, 2024

(30) Foreign Application Priority Data
Jun. 11, 2024 (CN) 202410750292.4

(51) Int. Cl. H01L 23/532; H01L 23/528; H10B 43/10; H10B 43/27; H10B 43/35

(52) U.S. Cl. CPC H01L 23/53295; H01L 23/5283; H10B 43/10; H10B 43/27; H10B 43/35

(57) ABSTRACT

The present disclosure relates to methods, devices, systems, and techniques for managing contact structures in semiconductor devices. An example semiconductor device includes a first semiconductor structure. The first semiconductor structure includes: a first stack of conductive layers and isolating layers alternating with each other along a first direction; a second stack of conductive layers and isolating layers alternating with each other along the first direction; a semiconductor layer between the first stack and the second stack along the first direction; a contact structure connected to the semiconductor layer, where the contact structure extends through the first stack, the semiconductor layer, and the second stack along the first direction; and a channel structure extending through the first stack, the semiconductor layer, and the second stack along the first direction, where the semiconductor layer is in contact with a channel layer of the channel structure.

### CROSS-REFERENCE TO RELATED APPLICATIONS

This application claims priority to Chinese Patent Application No. 202410750292.4, filed on Jun. 11, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a first semiconductor structure. The first semiconductor structure includes: a first stack of conductive layers and isolating layers alternating with each other along a first direction; a second stack of conductive layers and isolating layers alternating with each other along the first direction; a semiconductor layer between the first stack and the second stack along the first direction; a contact structure connected to the semiconductor layer, where the contact structure extends through the first stack, the semiconductor layer, and the second stack along the first direction; and a channel structure extending through the first stack, the semiconductor layer, and the second stack along the first direction, where the semiconductor layer is in contact with a channel layer of the channel structure.

In some implementations, the first stack includes at least a first deck including one or more of the conductive layers and isolating layers in the first stack, and the contact structure includes a first segment extending through the first deck along the first direction.

In some implementations, the first stack further includes a second deck including one or more of the conductive layers and isolating layers in the first stack, and the contact structure further includes a second segment extending through the second deck along the first direction and a third segment extending through the second stack.

In some implementations, the channel structure includes a first segment, a second segment, and a third segment, the first segment of the channel structure extends through the first deck along the first direction, the second segment of the channel structure extends through the second deck along the first direction, and the third segment of the channel structure extends through the second stack along the first direction.

In some implementations, a quantity of the one or more conductive layers in the first deck is in a range between 3 to 10.

In some implementations, the semiconductor device further includes a second semiconductor structure. The second semiconductor structure is bonded to the first semiconductor structure along the first direction through a bonding structure. The second semiconductor structure includes a control circuit configured to control the channel structure of the first semiconductor structure.

In some implementations, the first semiconductor structure includes a first interconnect layer coupled to the contact structure, and the first interconnect layer is coupled to the second semiconductor structure through the bonding structure.

In some implementations, the second semiconductor structure includes a second interconnect layer coupled to the first interconnect layer through the bonding structure.

In some implementations, the channel structure includes a first end coupled to a first bit line extending along a second direction perpendicular to the first direction and a second end coupled to a second bit line extending along the second direction, the first bit line is coupled to the control circuit of the second semiconductor structure, and the first bit line is coupled to the second bit line through a bit line contact structure extending along the first direction.

In some implementations, the contact structure includes at least one of a metallic material, a polysilicon, or a titanium nitride (TiN).

Another aspect of the present disclosure features a method including forming a first stack of sacrificial layers and isolating layers of a first semiconductor structure, where the first stack of sacrificial layers and isolating layers alternate with each other along a first direction; forming a second stack of sacrificial layers and isolating layers of the first semiconductor structure, where the second stack of sacrificial layers and isolating layers alternate with each other along the first direction; forming a semiconductor layer of the first semiconductor structure, where the semiconductor layer is between the first stack and the second stack along the first direction; forming a contact structure of the first semiconductor structure, where the contact structure is connected to the semiconductor layer and extends through the first stack, the semiconductor layer, and the second stack along the first direction; and forming a channel structure of the first semiconductor structure, where the channel structure extends through the first stack, the semiconductor layer, and the second stack along the first direction, and a channel layer of the channel structure is in contact with the semiconductor layer.

In some implementations, forming the first stack includes forming a first deck of the first stack and a second deck of the first stack, where each of the first deck and the second deck includes one or more of the sacrificial layers and isolating layers in the first stack; forming the contact structure includes forming a first segment of a contact hole extending through the first deck along the first direction and a second segment of the contact hole extending through the second deck along the first direction; and forming the channel structure includes forming a first segment of a channel hole extending through the first deck along the first direction and a second segment of the channel hole extending through the second deck along the first direction, where the first segment of the channel hole and the first segment of the contact structure are formed by a first etching process, and the second segment of the channel hole and the second segment of the contact structure are formed by a second etching process.

In some implementations, forming the semiconductor layer of the first semiconductor structure includes forming a first stop layer, a sacrificial array common source (ACS) layer, and a second stop layer on top of the first stack, the sacrificial ACS layer being between the first stop layer and the second stop layer along the first direction; and forming the second stack includes forming the second stack on top of the second stop layer.

In some implementations, forming the contact structure includes forming a third segment of the contact hole extending through the second stack, the second stop layer, the sacrificial ACS layer, and the first stop layer along the first direction; and forming the channel structure includes forming a third segment of the channel hole extending through the second stack, the second stop layer, the sacrificial ACS layer, and the first stop layer along the first direction, where the third segment of the channel hole and the third segment of the contact structure are formed by a third etching process.

In some implementations, forming the contact structure includes depositing a dielectric material and a conductive material into the contact hole to form a dielectric layer of the contact structure and a conductive layer of the contact structure, respectively; and forming the channel structure includes forming a channel layer and a memory film in the channel hole, where the memory film surrounds the channel layer.

In some implementations, forming the semiconductor layer of the first semiconductor structure includes: removing the sacrificial ACS layer to form a space; removing a portion of the memory film of the channel structure to expose a portion of the channel layer of the channel structure; removing a portion of the dielectric layer of the contact structure to expose a portion of the conductive layer of the contact structure; and depositing a semiconductive material into the space to form the semiconductor layer.

In some implementations, the method further includes replacing the sacrificial layers in the first stack and the sacrificial layers in the second stack with conductive layers.

In some implementations, the method further includes: forming a first bit line and a first interconnect layer on a first side of the first semiconductor structure, where the first interconnect layer is coupled to the channel structure and the contact structure, and the first bit line extends along a second direction perpendicular to the first direction and is coupled to a first end of the channel structure; forming a second semiconductor structure including a control circuit configured to control the channel structure of the first semiconductor structure and a second interconnect layer; and bonding the first side of the first semiconductor structure to the second semiconductor structure through a bonding structure, where the first interconnect layer is coupled to the second interconnect layer through the bonding structure.

In some implementations, the method further includes: forming a second bit line extending along the second direction on a second side of the first semiconductor structure; and forming a bit line contact structure extending along the first direction, where the bit line contact structure is coupled to the first bit line and the second bit line.

A further aspect of the present disclosure features a memory system. The memory system includes: a memory device including a first semiconductor structure; and a memory controller coupled to the memory device and configured to control the memory device. The first semiconductor structure includes: a first stack of conductive layers and isolating layers alternating with each other along a first direction; a second stack of conductive layers and isolating layers alternating with each other along the first direction; a semiconductor layer between the first stack and the second stack along the first direction; a contact structure connected to the semiconductor layer, where the contact structure extends through the first stack, the semiconductor layer, and the second stack along the first direction; and a channel structure extending through the first stack, the semiconductor layer, and the second stack along the first direction, where the semiconductor layer is in contact with a channel layer of the channel structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIGS. 1A-1C illustrate an example semiconductor device.

FIGS. 2A-2ZZ illustrate an example process of manufacturing a semiconductor device.

FIG. 3 illustrates a flow chart of an example process of manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

In some 3D NAND memory devices, memory cells of a memory array are connected to each other using vertical channels and are drawn out by unified array common source (ACS) and drain metal line (e.g., bit line). The channel saturation current (Ion) of the memory device can characterize the performance of the memory device. In some implementations, the channel saturation current Ion of the memory device can have an impact on the threshold voltage (Vt) distribution, thereby reducing the performance of the memory device (e.g., generating more program/read/verify errors). Furthermore, because bit lines are connected to a page buffer, the level of the channel saturation current Ion can also affect the function of the page buffer. For example, if the channel saturation current of the memory device is too low, the function of the page buffer may fail, and thus a series of reliability issues of the memory device may occur. As the number of layers in the 3D NAND memory device gradually increases, the channel length gradually increases, causing the channel saturation current to decrease, thereby reducing the reliability and performance of the memory device in several aspects. In addition, a larger ACS resistance may cause a source line noise issue. Therefore, it is desirable to maintain or increase the channel saturation current of the 3D NAND memory device and decrease the ACS resistance with more layers being stacked.

To address one or more of the aforementioned issues, the techniques described in the present disclosure allow an ACS layer to be formed in the middle of the memory array (e.g., along a vertical direction) and two bit lines to be formed on both sides (e.g., top and bottom) of the memory array. In one or more implementations of the present disclosure, an example semiconductor device is provided. The semiconductor device can be a memory device (e.g., a 3D NAND memory device). The semiconductor device includes two stacks of alternating conductive layers and isolating layers along the vertical direction. The semiconductor device further includes a semiconductor layer (e.g., an ACS layer) between the two stacks along the vertical direction. A contact structure of the semiconductor device is connected to the semiconductor layer and extends through the two stacks and the semiconductor layer along the vertical direction. A channel structure of the semiconductor device also extends through the two stacks and the semiconductor layer along the vertical direction. The semiconductor layer is in contact with a channel layer of the channel structure.

Implementations of the present disclosure can provide one or more of the following technical advantages and/or benefits. First, the equivalent channel length of a memory array of a memory device may be reduced, thereby increasing the channel saturation current Ion. In some implementations, operations in the present disclosure may be introduced to form the ACS layer in the middle of the memory array and connect the top and bottom bit lines by using a bit line contact structure, such that the channel length of the memory array of the memory device is roughly halved by having two channels electrically connected in parallel. In addition, the contact structure can reduce a length of a conductive path between the ACS layer and a control circuit, thereby reducing the ACS resistance. Therefore, the reliability and performance of the 3D memory devices can be improved.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

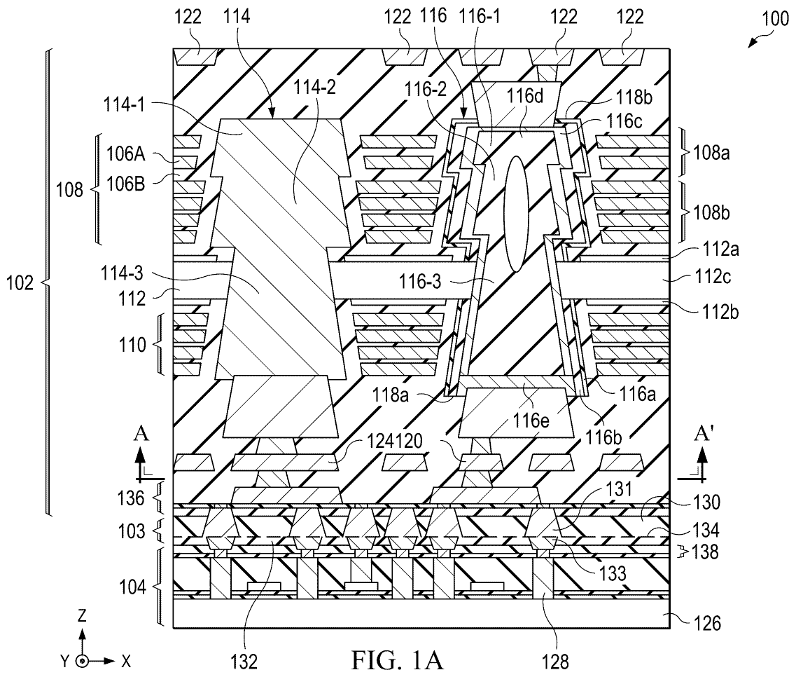

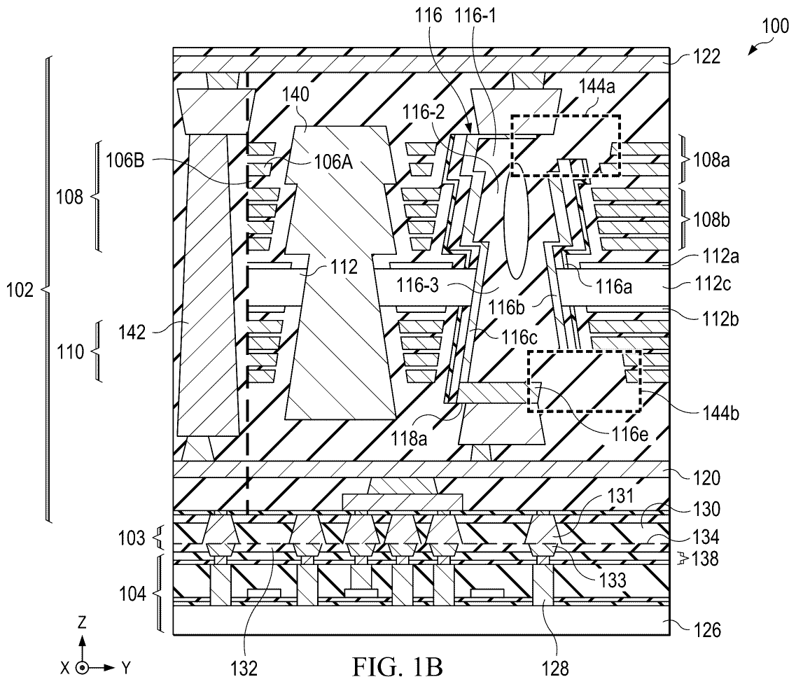

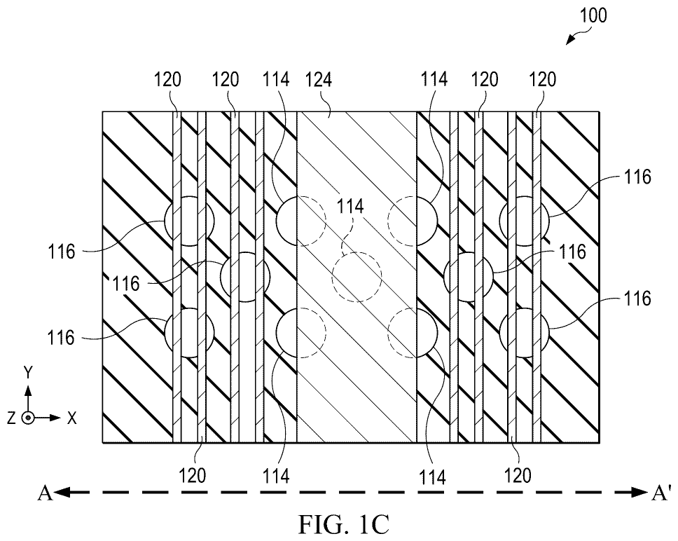

It is noted that X, Y, and Z axes (also referred to as X, Y, and Z directions) are included in FIGS. 1A-1C to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a side view of an example semiconductor device 100 along a horizontal direction (e.g., the Y direction). In some implementations, the semiconductor device 100 can be a memory device, such as a three-dimensional (3D) NAND memory device. The semiconductor device 100 can include a semiconductor structure 102 and a semiconductor structure 104 connected together. In some implementations, the semiconductor device 100 is a bonded chip including the semiconductor structure 102 stacked over the semiconductor structure 104. For example, the semiconductor structure 102 is bonded to the semiconductor structure 104 along a vertical direction (e.g., the Z direction) through a bonding structure 103. In other words, the semiconductor structures 102 and 104 can be jointed at a bonding structure 103 between the semiconductor structures 102 and 104 along the Z direction.

The semiconductor structure 102 includes conductive layers 106A and isolating layers 106B alternating with each other along the Z direction. Each of the conductive layers 106A and isolating layers 106B can extend in a horizontal plane (e.g., the X-Y plane perpendicular to the Z direction). The conductive layers 106A and isolating layers 106B in the semiconductor structure 102 can be divided by a semiconductor layer 112 into a stack 108 and a stack 110 arranged along the Z direction. In other words, the semiconductor layer 112 is between the stack 108 of conductive layers 106A and isolating layers 106B and the stack 110 of conductive layers 106A and isolating layers 106B along the Z direction. The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1A or 1B is for illustration only and that any suitable number of the conductive layers 106A and the isolating layers 106B can be included in the stack 108 or the stack 110 of the semiconductor structure 102. The conductive layers 106A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

In some implementations (not shown in FIGS. 1A-1C), the stack 108 or the stack 110 includes liner layers. Each of the liner layers can cover part or all sides of a corresponding conductive layer 106A and be between the conductive layer 106A and two isolating layers 106B adjacent to the corresponding conductive layer 106A. The liner layer can include a high-K dielectric material (e.g., Al₂O₃). In some examples, the conductive layer 106A includes a metallic material (e.g., W) and an adhesive material (e.g., TiN), and the adhesive material can be deposited between the metallic material and the high-K dielectric material. In some examples, the conductive layer 106A includes the metallic material (e.g., W), and the liner layer includes the adhesive material (e.g., TiN) and the high-K dielectric material.

In some implementations, the stack 108 and the stack 110 each can include one or more decks. For example, as shown in FIG. 1A, the stack 108 can include a deck 108a, and the deck 108a includes one or more of the conductive layers 106A and isolating layers 106B in the stack 108. In some instances, as shown in FIG. 1A, the stack 108 can include another deck 108b, which includes one or more of the conductive layers 106A and isolating layers 106B in the stack 108. The deck 108a can be stacked on the deck 108b along the Z direction. In some implementations, the deck 108a can be the deck that is farthest away from the semiconductor layer 112 among decks of the semiconductor structure 102. In some implementations, the deck 108a can have less conductive layers 106A and isolating layers 106B than the deck 108b. For example, a quantity of the conductive layers 106A in the deck 108a is in a range between 3 to 10, and a quantity of the conductive layers 106A in the deck 108b is in a range between 150 and 500.

The semiconductor layer 112 can extend in the X-Y plane (e.g., perpendicular to the Z direction). In some implementations, semiconductor layer 112 may include a first semiconductor layer 112a, a second semiconductor layer 112b, and a middle semiconductor layer 112c. The material of the first semiconductor layer 112a and the second semiconductor layer 112b can include polysilicon, e.g., undoped polysilicon. The middle semiconductor layer 112c may include doped polysilicon, e.g., p-doped polysilicon or n-doped polysilicon. The semiconductor layer 112 can function as an array common source (ACS) of a memory cell array (e.g., formed by the channel structures 116 described as below) in the semiconductor device 100. In some implementations, the semiconductor layer 112 also can be referred to as an ACS layer.

The semiconductor structure 102 includes one or more contact structures 114 connected to the semiconductor layer 112. Each contact structure 114 can extend through the stack 108, the semiconductor layer 112, and the stack 110 along the Z direction. The contact structure 114 can include any suitable conducting material, such as W, Co, Cu, Al, TiN, polysilicon, doped silicon, silicides, or any combination thereof. In some implementations, the contact structure 114 includes at least one of a metallic material, polysilicon, or TiN.

In some implementations, the contact structure 114 can include multiple segments. Each of the multiple segments extends through a respective deck of the stack 108 or the stack 110. For example, as shown in FIG. 1A, the contact structure 114 includes a first segment 114-1 extending through the deck 108a of the stack 108 along the Z direction, a second segment 114-2 extending through the deck 108b of the stack 108 along the Z direction, and a third segment 114-3 extending through the stack 110 along the Z direction.

The semiconductor structure 102 includes an array of channel structures 116. Each channel structure 116 can extend through the stack 108, the semiconductor layer 112, and the stack 110 along the Z direction. In some examples, the channel structure 116 can be in the shape of a cylinder or a pillar, and can include a high-K layer 116a, a block layer surrounded by the high-K layer, a charge trapping layer (or a storage layer) surrounded by the block layer, a tunneling layer surrounded by the charge trapping layer, a channel layer 116c surrounded by the tunneling layer, and a core filler layer 116d surrounded by the channel layer 116c, and a channel plug 116e formed above the core filler layer 116d and being in contact with the channel layer 116c. In some implementations, the channel layer 116c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer, and the blocking layer, collectively referred to as a memory film 116b, can include ONO dielectrics (silicon Oxide-silicon Nitride-silicon Oxide).

In some implementations, each channel structure 116 can include multiple segments. Each segment extends through a respective deck of the stack 108 or the stack 110. For example, as shown in FIG. 1A, the channel structure 116 includes a first segment 116-1 extending through the deck 108a of the stack 108 along the Z direction, a second segment 116-2 extending through the deck 108b of the stack 108 along the Z direction, and a third segment 116-3 extending through the stack 110 along the Z direction.

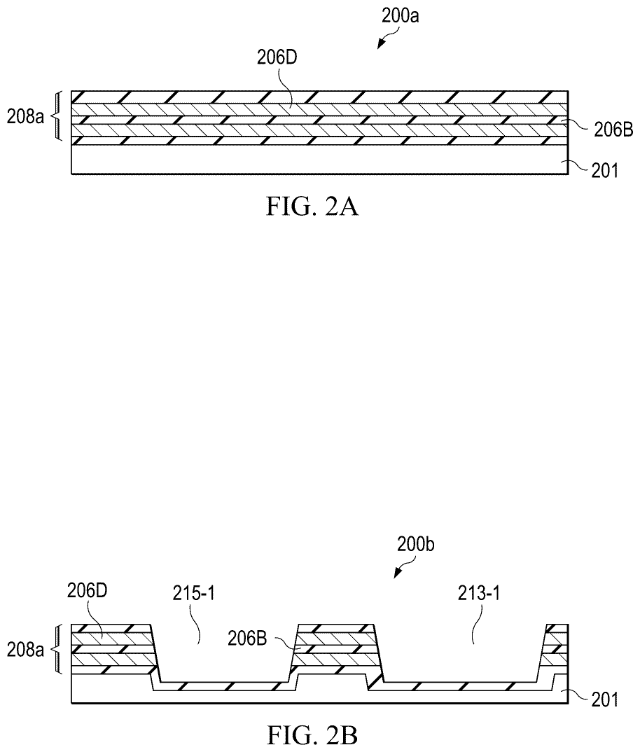

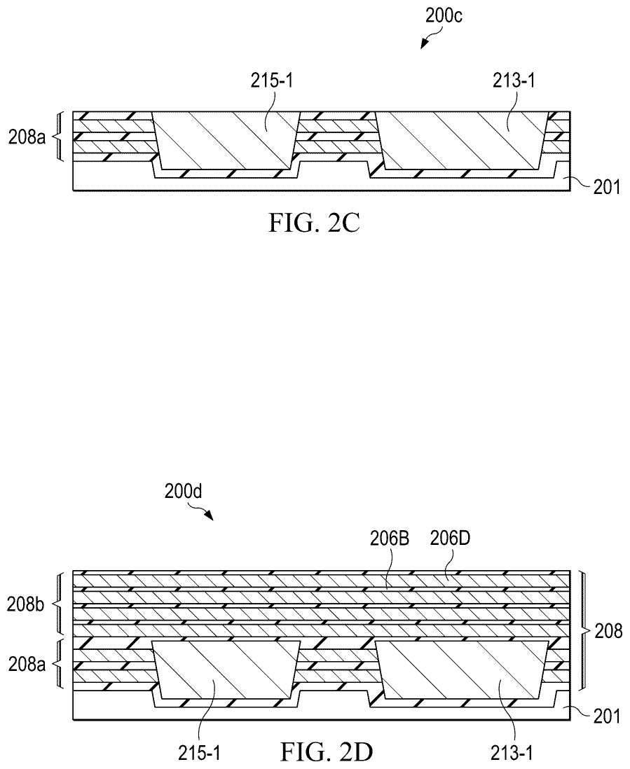

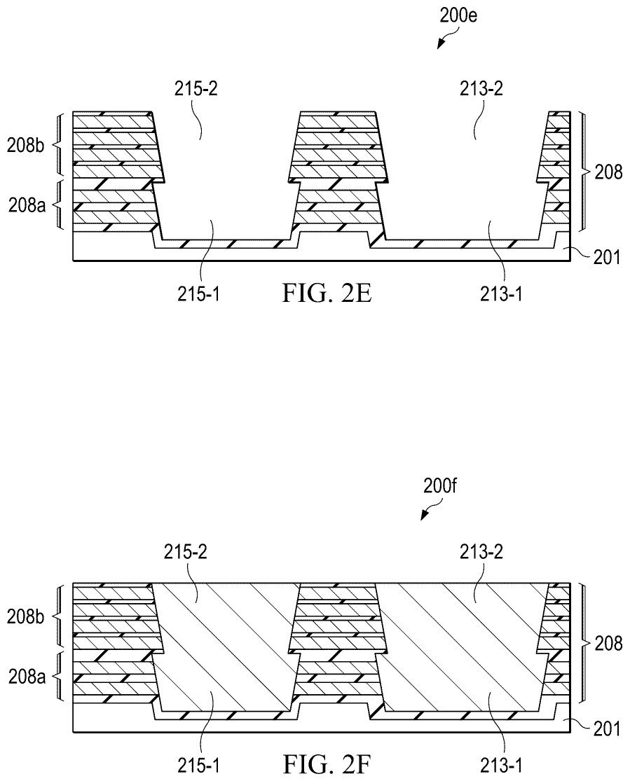

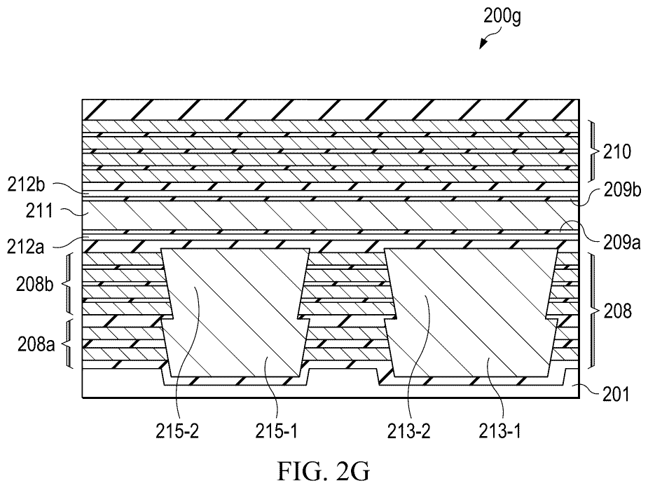

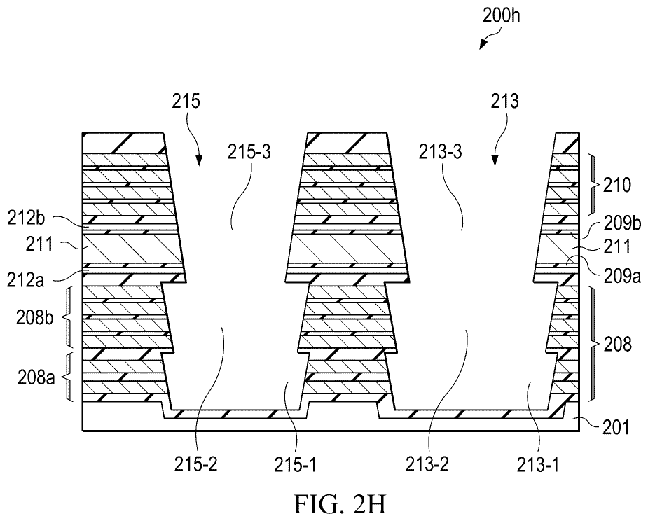

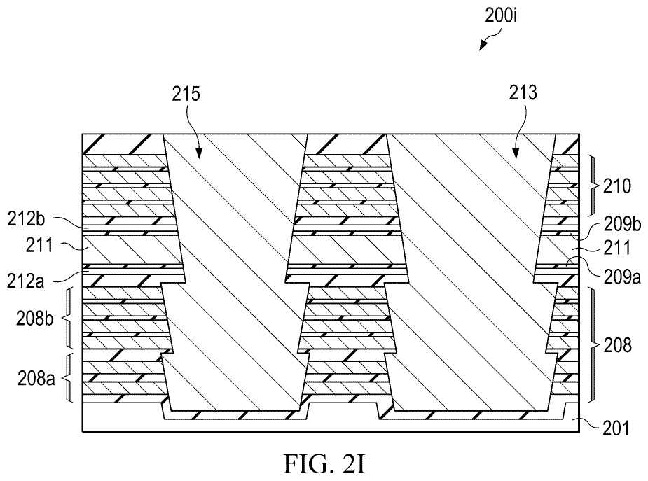

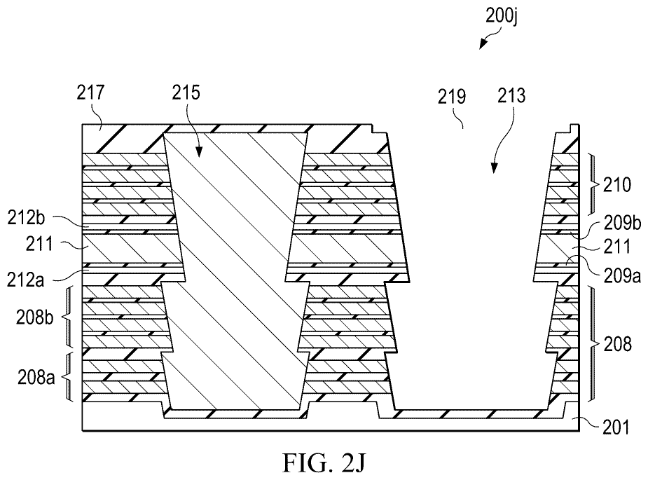

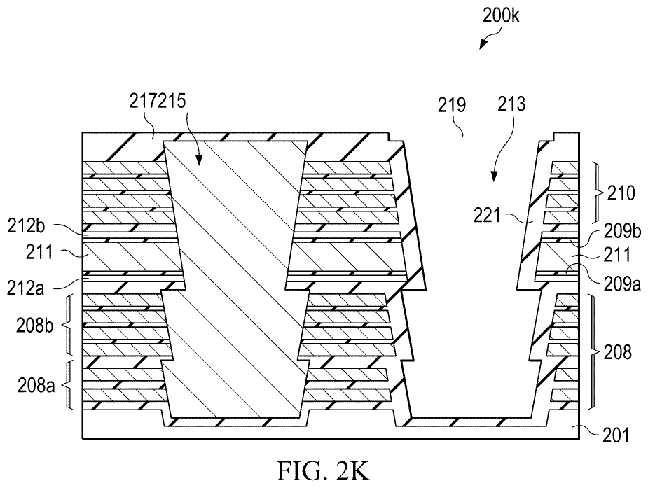

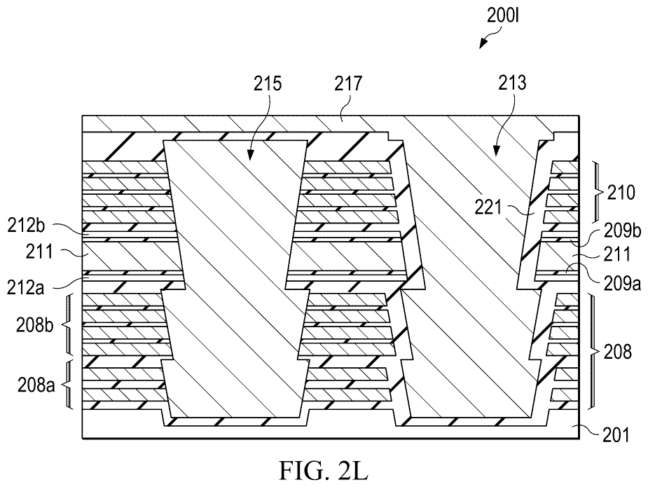

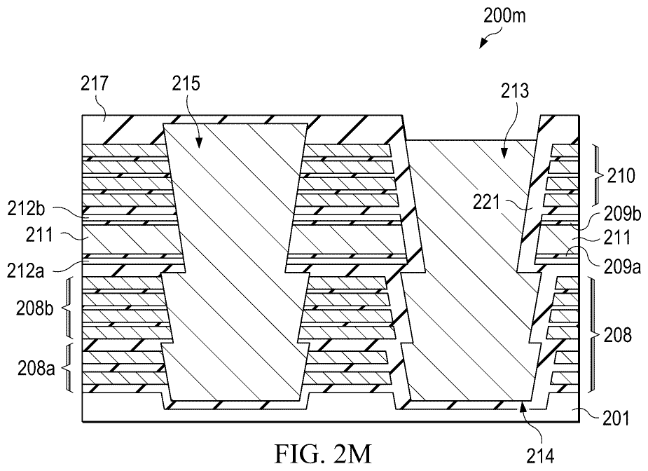

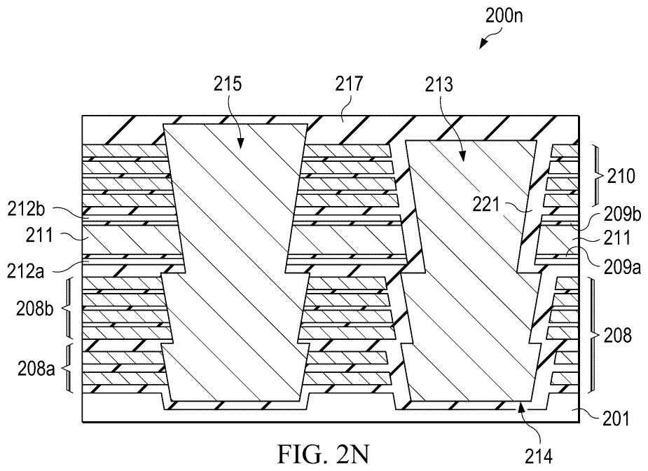

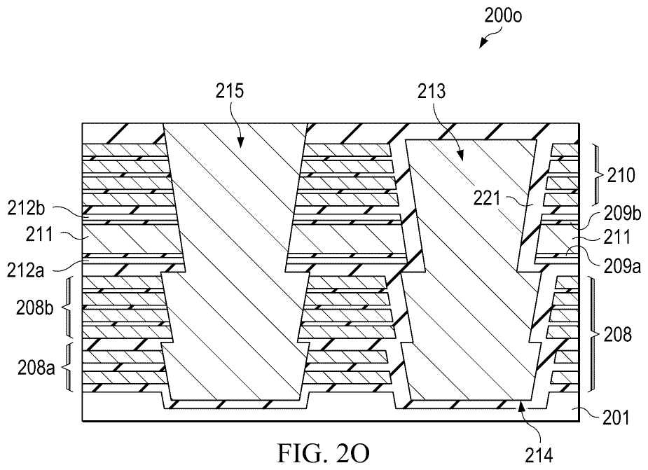

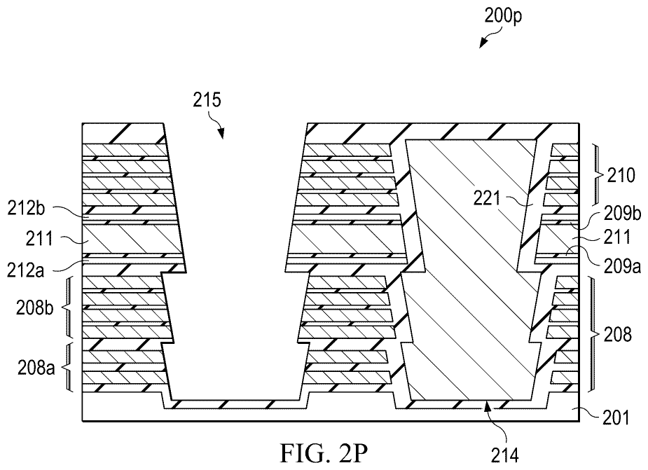

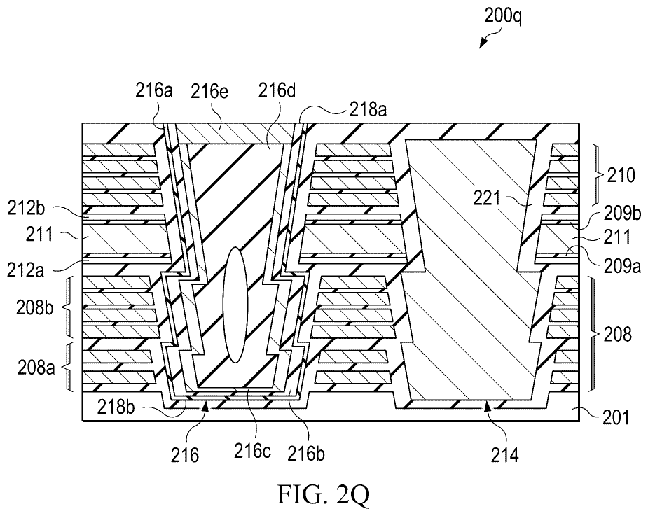

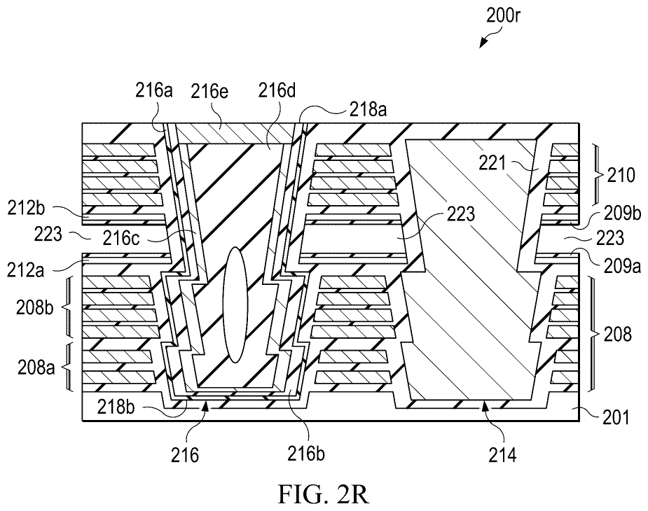

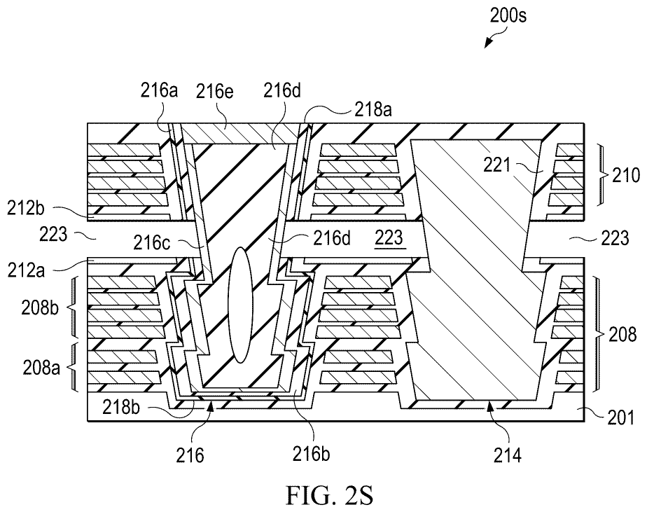

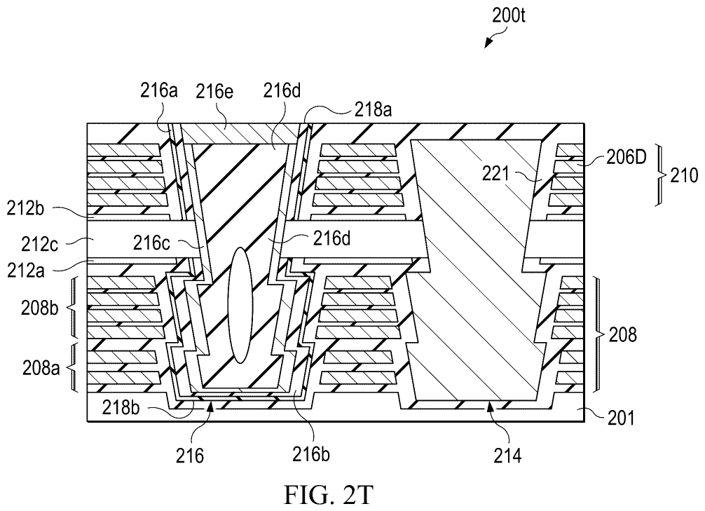

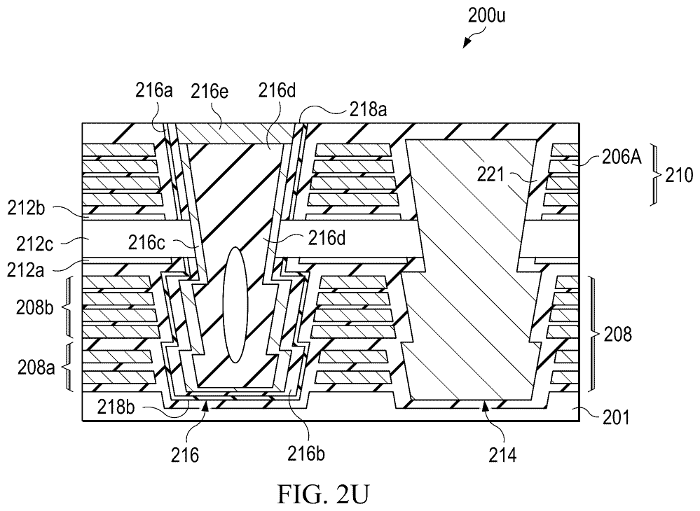

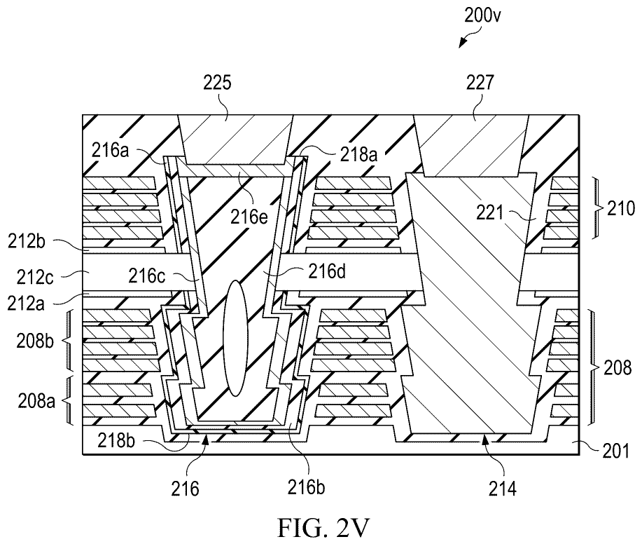

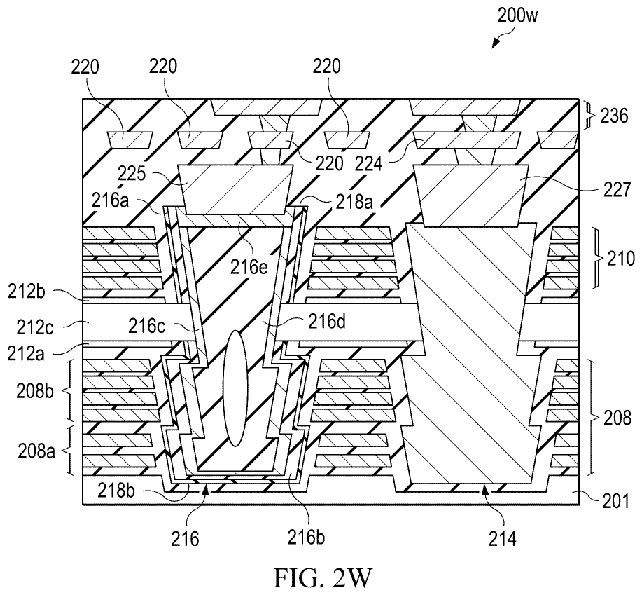

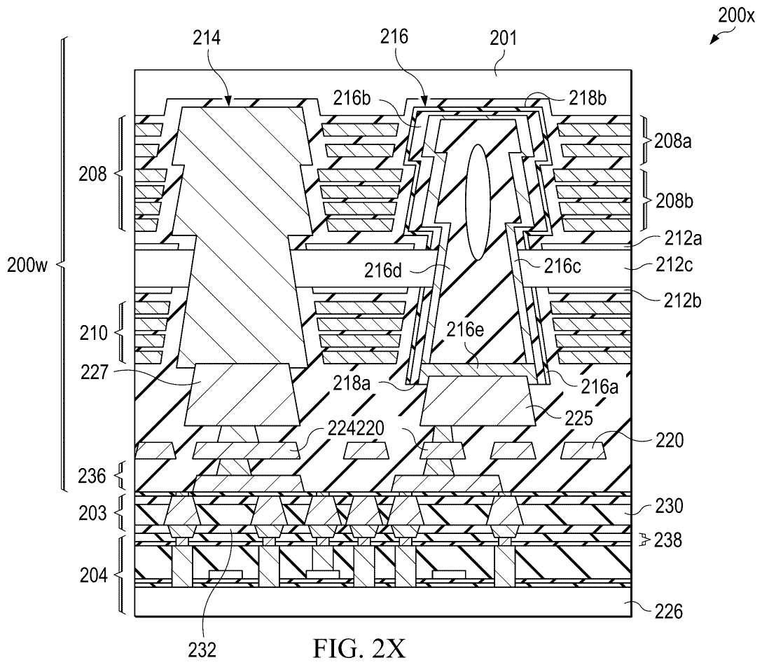

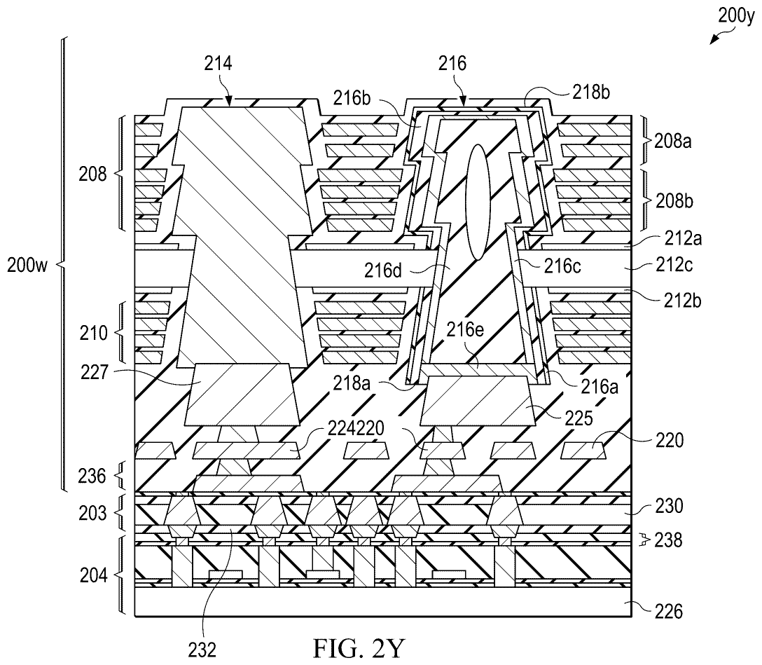

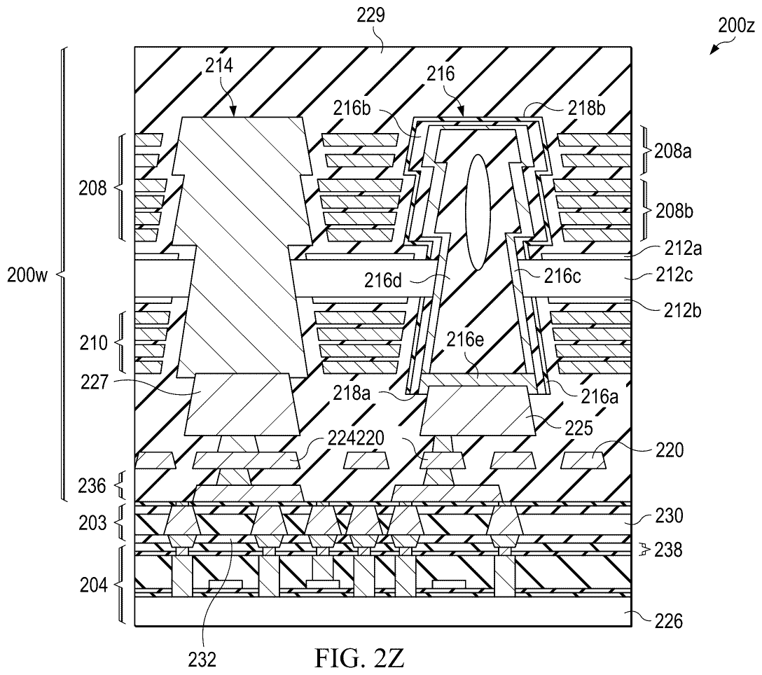

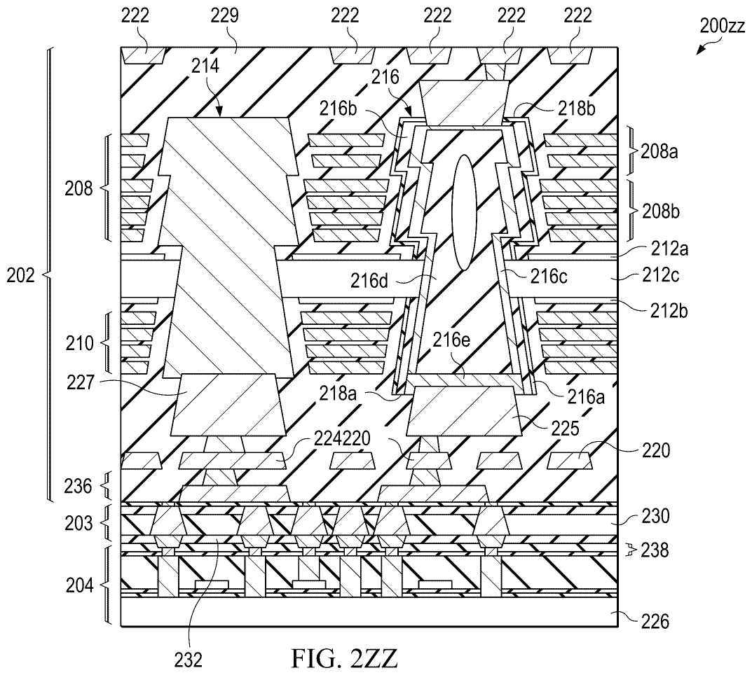

The semiconductor layer 112 can be in contact with the channel layer 116c of each respective channel structure in the array of channel structures 116. The semiconductor layer 112 can be in contact with the one or more contact structures 114. As shown in FIG. 2A, the semiconductor layer 112 can be in contact with the channel layer 116c and the contact structure 114 along a horizontal direction (e.g., the X direction or any suitable direction in the X-Y plane). In other words, a portion of the semiconductor layer 112, the channel layer 116c, and the contact structure 114 can be disposed along the horizontal direction.

The channel structure 116 has two ends 118a and 118b disposed opposite to each other along the Z direction. A bit line 120 is coupled to the channel layer 116c at the end 118a. In some implementations, the channel layer 116c at the end 118a includes the channel plug 116e. A bit line 122 is coupled to the channel layer 116c at the end 118b. In some implementations, the channel layer 116c at the end 118b includes another channel plug. The bit line 120 and the bit line 122 can extend along the Y direction. In some implementations, the bit lines 120 and 122 are disposed on two opposite sides of the structure formed by the stack 108, the semiconductor layer 112, and the stack 110. In some implementations, the bit line 120 is between the semiconductor structure 104 and the semiconductor layer 112 along the Z direction, and the semiconductor layer 112 is between the bit line 122 and the semiconductor structure 104 along the Z direction. A connection line 124 is coupled to an end of the contact structure 114. The connection line 124 can include any suitable conducting material, such as W, Co, Cu, Al, TiN, polysilicon, doped silicon, silicides, or any combination thereof. The connection line 124 can also extend along the Y direction (e.g., parallel to the bit lines 120 and 122). In some implementations, the connection line 124 can be on the same side of one of the bit lines 120 and 122 (e.g., bit line 120 as shown in FIG. 1A). In other words, the connection line 124 is between the contact structure 114 and the semiconductor structure 104 along the Z direction.

As shown in FIG. 1A, the semiconductor structure 104 can include a substrate 126, which can include silicon (e.g., single crystalline silicon, c-Si), SiGe, GaAs, Ge, SOI, or any other suitable materials. The semiconductor structure 104 can include peripheral circuits 128 on and/or in the substrate 126. In some implementations, the peripheral circuits 128 can include a control circuit configured to control the channel structures 116 of the semiconductor structure 102. In some implementations, the peripheral circuits 128 include one or more transistors. In some examples, the peripheral circuits 128 are formed using complementary metal-oxide-semiconductor (CMOS) technology, and the semiconductor structure 104 can be also formed on a semiconductor die that can be referred to as a control die, a CMOS die, or a CMOS wafer. In some implementations, the semiconductor structure 102 can be referred to as an array die or an array wafer.

As shown in FIG. 1A, the bonding structure 103 can include a bonding layer 130 and a bonding layer 132 jointed at a bonding interface 134 therebetween. The bonding layer 130 can include a plurality of bonding contacts 131 and dielectric materials electrically isolating the bonding contacts 131. The bonding contacts 131 can include conductive materials, such as Cu. The remaining area of the bonding layer 130 can be formed with the dielectric materials, such as silicon oxide. The bonding contacts 131 and the surrounding dielectric materials in the bonding layer 130 can be used for hybrid bonding. The bonding layer 132 can include a plurality of bonding contacts 133 and dielectric materials electrically isolating the bonding contacts 133. The bonding contacts 133 can include conductive materials, such as Cu. The remaining area of the bonding layer 132 can be formed with the dielectric materials, such as silicon oxide. The bonding contacts 133 and the surrounding dielectric materials in the bonding layer 132 can be used for hybrid bonding. The bonding contacts 131 can be in contact with the bonding contacts 133 at the bonding interface 134. In some implementations, the bonding layer 130 can be considered as a part of the semiconductor structure 102, and the bonding layer 132 can be considered as a part of the semiconductor structure 104. The semiconductor structure 104 can be bonded to the semiconductor structure 102 in a face-to-face manner at the bonding interface 134. In some implementations, the bonding interface 134 is disposed between the bonding layers 130 and 132 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 134 is the place at which bonding layers 130 and 132 are met and bonded. In some examples, the bonding interface 134 can be a layer with a certain thickness that includes the top surface of the bonding layer 132 and the bottom surface of the bonding layer 130.

In some implementations, the semiconductor structure 102 includes an interconnect layer 136. The interconnect layer 136 can be coupled to the connection line 124 and the bit line 120 and can be configured to transfer electrical signals to and from the connection line 124 and the bit line 120. That is, the contact structure 114 is coupled to the interconnect layer 136 through the connection line 124, and the channel structure 116 is coupled to the interconnect layer 136 through the bit line 120. The interconnect layer 136 can be between the stack 110 and the bonding layer 130 along the Z direction. The interconnect layer 136 can be coupled to the semiconductor structure 104 through the bonding structure 103. For example, the interconnect layer 136 can be coupled to the bonding contacts 131 of the bonding layer 130. The interconnect layer 136 can include a plurality of interconnects (also referred to as “contacts”), including lateral interconnect lines and vertical interconnect access (VIA) contacts. The interconnect layer 136 can further include one or more interlay dielectric (ILD) layers in which the interconnect lines and VIA contacts can form. That is, the interconnect layer 136 can include interconnect lines and VIA contacts in multiple ILD layers. The interconnects in interconnect layer 136 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the semiconductor structure 104 includes an interconnect layer 138. The interconnect layer 138 is between the bonding layer 132 and the peripheral circuits 128 along the Z direction. The interconnect layer 138 can be coupled to the bonding contacts 133 of the bonding layer 132. In other words, the interconnect layer 136 of the semiconductor structure 102 is coupled to the interconnect layer 138 of the semiconductor structure 104 through the bonding structure 103, and the peripheral circuits 128 of the semiconductor structure 104 are coupled to the semiconductor structure 102 through the interconnect layer 138 and the bonding structure 103. Similar to the interconnect layer 136, the interconnect layer 138 also can include a plurality of interconnects, including lateral interconnect lines and VIA contacts. The interconnect layer 138 can further include one or more ILD layers in which the interconnect lines and VIA contacts can form. That is, the interconnect layer 138 can include interconnect lines and VIA contacts in multiple ILD layers. The interconnects in interconnect layer 138 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

FIG. 1B illustrates a side view of the semiconductor device 100 along another horizontal direction (e.g., the X direction). In some implementations, as shown in FIG. 1B, the semiconductor device 100 includes one or more gate line structures 140. The gate line structures 140 can extend along a horizontal direction (e.g., the X direction) to divide the semiconductor structure 102 into multiple blocks (e.g., memory blocks). Each of the gate line structures 140 can extend through the stack 108, the semiconductor layer 112, and the stack 110 along the Z direction. In some implementations, the gate line structure 140 is not in contact with the semiconductor layer 112. For example, a dielectric spacer (e.g., silicon oxide) can isolate the gate line structure 140 from the semiconductor layer 112 (e.g., in the X-Y plane). In some implementations, the gate line structure 140 can include any suitable semiconductor material such as polysilicon.

As shown in FIG. 1B, the semiconductor device 100 can include one or more bit line contact structures 142. Each bit line contact structure 142 can extend along the Z direction and couple a bit line (e.g., the bit line 120) on one side (e.g., along the Z direction) of the channel structure 116 and another bit line (e.g., the bit line 122) one the other side (e.g., along the Z direction) of the channel structure 116. The bit line contact structures 142 may not extend through the stack 108, the semiconductor layer 112, and the stack 110. For example, as shown in FIG. 1B, the bit line contact structure 142 can be disposed in an area adjacent to an edge of the stack 108, the semiconductor layer 112, and the stack 110 in a horizontal direction (e.g., in the Y direction). In this way, the manufacturing of the bit line contact structure 142 can be more efficient because it may take a longer time to form a hole (e.g., by etching) that extend through the stack 108, the semiconductor layer 112, and the stack 110.

The semiconductor device 100 can include a top select gate (TSG) 144a and a TSG 144b disposed on both sides of the semiconductor structure 102 along the Z direction. Each of the TSGs 144a and 144b can divide a memory block into multiple portions. In some instances, as shown in FIG. 1B, each TSG (e.g., TSG 144a or TSG 144b) can extend through (e.g., along the Z direction) one or more outmost conductive layers 106A in the stack 108 or the stack 110 in the semiconductor structure 102.

In some implementations, the semiconductor structure 102 can include one or more array regions (not shown in FIG. 1A) and one or more connection regions (not shown in FIG. 1A) configured to provide conductive connections for the one or more array regions. An array region can be adjacent to a connection region along the X direction. In practice, any suitable arrangement of various regions in the semiconductor structure 102 can be applied. For example, the semiconductor structure 102 can have two connection regions and an array region arranged between the two connection regions along the X direction. In some other instances, the semiconductor structure 102 can have two array regions and a connection region between the two array regions along the X direction. In some implementations, the semiconductor structure 102 can include dummy channel structures (not shown in FIG. 1A) for process variation control during fabrication and/or for additional mechanical support. In some implementations, the dummy channel structures are in a connection region. For example, some dummy channel structures can be in an edge or peripheral area of the connection region. In some instances, the edge area of the connection region is adjacent to an array region. In some other instances, the edge area of the connection region is adjacent to a gate line structure (e.g., gate line structure 140 as shown in FIG. 1B). In some implementations, the dummy channel structures are in the array region (e.g., an area adjacent to the connection region). In some implementations, the contact structures 114 and the array of channel structures 116 can be in the array region. In some implementations, the contact structures 114 and the array of channel structures 116 can be in any other suitable region (e.g., a connection region).

FIG. 1C illustrates a cross-sectional view of the semiconductor device 100 along a cut line AA′ of FIG. 1A. As shown in FIG. 1C, the connection line 124 and the bit lines 120 can extend in parallel along the Y direction. Each bit line 120 can be connected to a corresponding channel structure 116. The connection line 124 can be connected to multiple contact structures 114 and has a larger width (e.g., a size along the X direction) than the bit line 120. In this way, the resistance (e.g., the ACS resistance) caused by the contact structures 114 and the connection line 124 can be reduced, thereby improving the performance of the semiconductor device 100.

FIGS. 2A-2Z illustrate an example process of fabricating a semiconductor device, such as the semiconductor device 100 as illustrated in FIGS. 1A-1C. FIGS. 2A-2Z show side views of example semiconductor structures at various stages of the fabrication process.

As shown in FIG. 2A, a semiconductor structure 200a is formed. The semiconductor structure 200a includes a substrate 201 and a deck 208a of sacrificial layers 206D and isolating layers 206B. The sacrificial layers 206D and isolating layers 206B can alternate with each other along the vertical direction (e.g., the Z direction). The substrate 201 and each of the sacrificial layers 206D and isolating layers 206B can extend in the X-Y plane. The semiconductor structure 200a can formed by, for example, depositing the deck 208a of sacrificial layers 206D and isolating layers 206B on top of the substrate 201. The isolating layers 206B can include dielectric material, such as silicon oxide, silicon nitride, silicon oxynitride, or any combination thereof. In some implementations, the sacrificial layers 206D can include a dielectric material different from the dielectric material of the isolating layers 206B. For example, the isolating layers 206B can include silicon oxide, and the sacrificial layers 206D can include silicon nitride.

FIG. 2B shows a semiconductor structure 200b including one or more contact holes 213-1 and one or more channel holes 215-1. The contact holes 213-1 and the channel holes 215-1 extend through the deck 208a and into the substrate 201 along the Z direction. In some implementations, the contact holes 213-1 and the channel holes 215-1 can be formed by a same etching process (e.g., a first etching process). Due to the etching process, in some implementations, diameters (e.g., a size of a cross section of each hole in a horizontal direction) of the contact holes 213-1 and the channel holes 215-1 can gradually decrease along the vertical direction from top to bottom. Thus, a size of the bottom area of each of the contact holes 213-1 and the channel holes 215-1 can be determined by a height of the deck 208a along the vertical direction (e.g., the Z direction). When the deck 208a has less layers, its height can be smaller, and thus the bottom area of the contact holes 213-1 and the channel holes 215-1 can be larger. As shown below in some later processes (e.g., as described with reference to FIGS. 2B-2ZZ), the size of the bottom area of the contact holes 213-1 and the channel holes 215-1 can determine a size of a landing area at one end of a contact structure (e.g., the contact structure 214 of FIG. 2ZZ) or a channel structure (e.g., the channel structure 216 of FIG. 2ZZ) formed in these holes. It can be easier to connect conductive structures to the landing area at the end of the contact structure or the channel structure if the landing area has a larger size. Thus, the deck 208a can have less layers so that the landing area at the end of the contact structure or the channel structure formed later can have a larger size. In some implementations, a quantity of the sacrificial layers 206D in the deck 208a can be in a range between 3 to 10.

As shown in FIG. 2C, a semiconductor structure 200c is formed by, for example, filling a filler material (e.g., polysilicon) into the contact holes 213-1 and the channel holes 215-1.

FIG. 2D shows a semiconductor structure 200d including a deck 208b of sacrificial layers 206D and isolating layers 206B. The sacrificial layers 206D and isolating layers 206B in the deck 208b can alternate with each other along the vertical direction (e.g., the Z direction). The deck 208a and the deck 208b can form a stack 208. The semiconductor structure 200d can be formed, for example, by depositing the deck 208b of sacrificial layers 206D and isolating layers 206B on top of the deck 208a. In some implementations, a quantity of the sacrificial layers 206D in the deck 208b can be in a range between 150 to 500.

FIG. 2E shows a semiconductor structure 200e including contact holes 213-2 and channel holes 215-2 in the deck 208b. The contact holes 213-2 and the channel holes 215-2 can be formed by a same etching process (e.g., a second etching process). The contact holes 213-2 and the channel holes 215-2 can extend through the deck 208b along the Z direction. Each of the contact holes 213-2 can be disposed on top of a corresponding contact hole 213-1 and expose the filler material in the contact hole 213-1. Each of the channel holes 215-2 can be disposed on top of a corresponding channel hole 215-1 and expose the filler material in the channel hole 215-1. As shown in FIG. 2E, the filler material in the contact holes 213-1 and the channel holes 215-1 can be removed so that each contact hole 213-2 and the corresponding contact hole 213-1 are connected, and each channel hole 215-2 and the corresponding channel hole 215-1 also are connected.

As shown in FIG. 2F, a semiconductor structure 200f is formed by, for example, filling a filler material (e.g., polysilicon) into the contact holes 213-1 and 213-2 and the channel holes 215-1 and 215-2.

FIG. 2G shows a semiconductor structure 200g. The semiconductor structure 200g can be formed by sequentially depositing a stop layer (also referred to as a semiconductor layer) 212a, an isolating layer 209a, a sacrificial array common source (ACS) layer 211, an isolating layer 209b, and a stop layer (also referred to as a semiconductor layer) 212b on top of the stack 208 (e.g., the deck 208b on the top). The semiconductor structure 200g further includes a stack 210 of sacrificial layers 206D and isolating layers 206B alternating with each other along the vertical direction (e.g., the Z direction). The stack 210 can be stacked on top of the stop layer 212b. In some implementations, a quantity of the sacrificial layers 206D in the stack 210 can be in a range between 150 to 500.

The stop layers 212a and 212b can include a semiconductor material such as polysilicon. The isolating layers 209a and 209b can include a dielectric material. In some implementations, the dielectric material of the isolating layers 209a and 209b can be the same as the dielectric material (e.g., silicon oxide) of the isolating layers 206B. The sacrificial ACS layer 211 can include a material that has a higher etching selection ratio compared to the stop layers 212a and 212b. In other words, the material of the sacrificial ACS layer 211 can be etched off at a higher etching rate than the stop layers 212a and 212b. For example, the material of the sacrificial ACS layer 211 can be the same as the material (e.g., silicon nitride) of the sacrificial layers 206D. In another example, the material of the sacrificial ACS layer 211 can be carbon-doped polysilicon.

FIG. 2H shows a semiconductor structure 200h including contact holes 213 and channel holes 215. The semiconductor structure 200h can be formed by forming contact holes 213-3 and channel holes 215-3 using a same etching process (e.g., a third etching process). The contact holes 213-3 and the channel holes 215-3 can extend through the stack 210, the stop layer 212b, the isolating layer 209b, the sacrificial ACS layer 211, the isolating layer 209a, and the stop layer 212a along the Z direction. Each of the contact holes 213-3 can be disposed on top of a corresponding contact hole 213-2 and expose the filler material in the contact hole 213-2. Each of the channel holes 215-3 can be disposed on top of a corresponding channel hole 215-2 and expose the filler material in the channel hole 215-2. As shown in FIG. 2H, the filler material in the contact holes 213-1 and 213-2 and the channel holes 215-1 and 215-2 can be removed. In this way, each contact hole 213-3, the corresponding contact hole 213-2, and the corresponding contact hole 213-1 are connected to form the contact hole 213. The contact holes 213-1, 213-2, 213-3 can be considered as a first segment, a second segment, and a third segment of the contact hole 213, respectively. Similarly, each channel hole 215-3, the corresponding channel hole 215-2, and the corresponding channel hole 215-1 are connected to form the channel hole 215. The channel holes 215-1, 215-2, 215-3 can be considered as a first segment, a second segment, and a third segment of the channel hole 215, respectively.

As shown in FIG. 2I, a semiconductor structure 200i is formed by, for example, filling a filler material (e.g., polysilicon) into the contact holes 213 and the channel holes 215.

FIG. 2J shows a semiconductor structure 200j. The semiconductor structure 200j can be formed by depositing a dielectric layer 217 on top of the semiconductor structure 200i. The dielectric layer 217 can include any suitable dielectric material such as silicon oxide. Openings 219 can be formed in the dielectric layer 217 to expose the filler material in the contact holes 213. Then the filler material in the contact holes 213 can be removed.

As shown in FIG. 2K, a semiconductor structure 200k is formed by, depositing a dielectric layer 221 on an interior sidewall and a bottom of each contact hole 213. The dielectric layer 221 can include any suitable dielectric material such as silicon oxide.

As shown in FIG. 2L, a semiconductor structure 200l is formed by, filling a conductive material into the contact holes 213. The conductive material can include any suitable conducting material, such as W, Co, Cu, Al, TiN, polysilicon, doped silicon, silicides, or any combination thereof. In some implementations, the conductive material includes at least one of a metallic material, polysilicon, or TiN.

FIG. 2M shows a semiconductor structure 200m including a contact structure 214 in each of the contact holes 213. The semiconductor structure 200m can be formed by removing the excess conductive material on top of the dielectric layer 217 by a planarization process, such as chemical mechanical polishing (CMP). A portion of the conductive material in the contact holes 213 also can be removed so that a remaining portion of the conductive material in the contact holes 213 is lower than the filler material in the channel holes 215. The contact structure 214 includes the remaining conductive material (also referred to as a conductive layer) in each of the contact holes 213. In some implementations, the dielectric layer 221 can also be considered as a part of the contact structure 214. In some implementations, the top of the contact structure 214 (e.g., an end that is farther away from the substrate 201 along the Z direction) can be lower than (e.g., closer to the substrate 201 along the Z direction) a top of the filler material in the channel holes 215.

As shown in FIG. 2N, a semiconductor structure 200n is formed by, filling a dielectric material into the contact holes 213 and the openings 219 to cover the contact structures 214.

As shown in FIG. 2O, a semiconductor structure 200o is formed by, removing the dielectric layer 217 to expose the filler material in the channel holes 215. The contact structures 214 can still be covered by the dielectric material in the contact holes 213.

As shown in FIG. 2P, a semiconductor structure 200p is formed by, removing the filler material in the channel holes 215.

FIG. 2Q shows a semiconductor structure 200q including a respective channel structure 216 in each of the channel holes 215. The channel structure 216 can be formed by sequentially depositing a high-K layer 216a, a block layer, a charge trapping layer, a tunneling layer, a channel layer 216c, and a core filler layer 216d into the channel hole 215. In some implementations, the channel layer 216c can include silicon, such as amorphous silicon, polysilicon, or single crystalline silicon. The tunneling layer can include silicon oxide, silicon nitride, or any combination thereof. The blocking layer can include silicon oxide, silicon nitride, high-K dielectrics, or any combination thereof. The charge trapping layer can include silicon nitride, silicon oxynitride, silicon, or any combination thereof. In some implementations, the tunneling layer, the charge trapping layer, and the blocking layer, collectively referred to as a memory film 216b, can include ONO dielectrics (silicon Oxide-silicon Nitride-silicon Oxide). The channel structure 216 has two ends 218a and 218b disposed opposite to each other along the Z direction. The channel structure 216 further includes a channel plug 216e formed at the end 218a. The channel plug 216e can be above the core filler layer 216d and be in contact with the channel layer 216c.

As shown in FIG. 2R, a semiconductor structure 200r including a space 223 is formed by removing the sacrificial ACS layer 211. The space 223 can expose a portion of the dielectric layer 221 (which was in contact with the sacrificial ACS layer 211) of the contact structure 214. The space 223 can also expose the dielectric material that was in contact with the sacrificial ACS layer 211 and surrounds the channel structure 216. The sacrificial ACS layer 211 can be removed by any suitable method. In some implementations, a gate line slit (not shown in FIG. 2R) that extends along the Z direction and exposes the sacrificial ACS layer 211 can be formed. For example, the gate line slit can extend from a top of the semiconductor structure 200r to the stop layer 212a. The sacrificial ACS layer 211 can be etched off by filling an etching solution into the gate line slit.

As shown in FIG. 2S, a semiconductor structure 200s is formed by expanding the space 223. The portion of the dielectric layer 221 exposed by the space 223 can be removed. Thus, the conductive layer of the contact structure 214 can be exposed by the expanded space 223. The channel layer 216c of the channel structure 216 also can be exposed by removing a portion of the memory film 216b and the high-K layer 216a of the channel structure 216 and the dielectric material surrounding the portion of the high-K layer 216a. The isolating layers 209a and 209b also can be removed.

As shown in FIG. 2T, a semiconductor structure 200t including a semiconductor layer 212 is formed. The semiconductor layer 212 includes the stop layer (also referred to as the semiconductor layer) 212a, the stop layer (also referred to as the semiconductor layer) 212b, and a semiconductor layer 212c. The semiconductor layer 212c can be formed by depositing a semiconductor material (e.g., n-doped polysilicon) into the expanded space 223. As a result, the semiconductor layer 212c is connected to the conductive layer of the contact structure 214 and is connected to the channel layer 216c of the channel structure 216.

FIG. 2U shows a semiconductor structure 200u. The sacrificial layers 206D in the stack 208 and the stack 210 (e.g., in the semiconductor structure 200t of FIG. 2T) are replaced with conductive layers 206A. The sacrificial layers 206D can be etched away, e.g., through an opening formed in the position of the gate line structure 140 of FIG. 1B. Then, the conductive layers 206A can be formed in replace of the sacrificial layers 206D to form a new stack 208 and a new stack 210.

As shown in FIG. 2V, a semiconductor structure 200v including a respective conductive contact 225 connected to each channel structure 216 and a respective conductive contact 227 connected to each contact structure 214 is formed. The conductive contact 225 can be in one side (e.g., a side farther away from the substrate 201 as shown in FIG. 2V) of the semiconductor structure 220v and is in contact with one end (e.g., the channel plug 216e) of the channel structure 216 in that side. The conductive contact 227 can be in that side and is in contact with one end of the contact structure in that side.

FIG. 2W shows a semiconductor structure 200w including bit lines 220 and a connection line 224. The bit lines 220 and the connection line 224 can be formed in the same side as the conductive contacts 225 and 227. Each bit line 220 can be coupled to a corresponding channel structure 216 through one of the conductive contacts 225. The connection line 224 can be coupled to one or more of the contact structures 214 through corresponding conductive contacts 227. The bit lines 220 and the connection line 224 extend along the Y direction. The semiconductor structure 200w further includes an interconnect layer 236 formed in the same side as the bit lines 220 and the connection line 224 (which can be referred to as a first side). The interconnect layer 236 can be coupled to the bit lines 220 and the connection line 224 and can be configured to transfer electrical signals to and from the channel structures 216 (e.g., through the bit lines 220 and the conductive contacts 225) and the contact structures 214 (e.g., through the connection line 224 and the conductive contacts 227).

FIG. 2X shows a semiconductor structure 200x, which can be formed by bonding the semiconductor structure 200w to a semiconductor structure 204. In some implementations, the semiconductor structure 200w and the semiconductor structure 204 can be fabricated in parallel. The semiconductor structure 204 can be an example of the semiconductor structure 104 of FIGS. 1A-1B. In some implementations, as shown in FIG. 2X, the semiconductor structure 204 can include a substrate 226 and peripheral circuits 228. The peripheral circuits 228 can include a control circuit configured to control the channel structures 216 of the semiconductor structure 200w. In some implementations, the semiconductor structure 204 further includes an interconnect layer 238 above the peripheral circuits 228 to transfer electrical signals to and from the peripheral circuits 228. Note that the semiconductor structure 200w is flipped upside down in FIG. 2X. The semiconductor structure 200w can be bonded to and coupled to the semiconductor structure 204 using any suitable bonding methods. For example, a bonding layer 230 can be formed on one side (e.g., the first side where the bit lines 220, the connection line 224, and the interconnect layer 236 are located) of the semiconductor structure 200w. The bonding layer 230 can be similar to, or same as, the bonding layer 130 of FIG. 1A. The bonding layer 230 can include conductive bonding contacts and a dielectric material isolating the bonding contacts in a horizontal direction (e.g., the X direction). The interconnect layer 236 can be coupled to the bonding contacts of the bonding layer 230. A bonding layer 232 can be formed on top of the interconnect layer 238 of the semiconductor structure 204. The bonding layer 232 can be similar to, or same as the bonding layer 132 of FIG. 1A. Similarly, the bonding layer 232 can include conductive bonding contacts and a dielectric material isolating the bonding contacts in a horizontal direction (e.g., the X direction). The interconnect layer 238 can be coupled to the bonding contacts of the bonding layer 232. In some implementations, the bonding layer 230 can be bonded to the bonding layer 232 using a direct bonding technology (e.g., forming bonding between surfaces without using intermediate layers, such as solder or adhesives) and can obtain metal-metal bonding and dielectric-dielectric bonding simultaneously. That is, the bonding contacts in the bonding layer 230 are bonded to the bonding contacts in the bonding layer 232, and the dielectric material in the bonding layer 230 is bonded to the dielectric material in the bonding layer 232. The bonding layers 230 and 232 can form a bonding structure 203. In other words, the interconnect layer 236 is coupled to the interconnect layer 238 through the bonding structure 203 (e.g., the conductive bonding contacts in the bonding structure 203).

FIG. 2Y shows a semiconductor structure 200y, which can be formed by removing the substrate 201 of the semiconductor structure 200w.

FIG. 2Z shows a semiconductor structure 200z, which can be formed by depositing a dielectric layer 229 on top of the semiconductor structure 200w. The dielectric layer 229 can include any suitable dielectric material such as silicon oxide. In some implementations, a planarization process (e.g., CMP) can be applied on top of the semiconductor structure 200z (also on top of the new semiconductor structure 200w) to form a smooth top surface.

FIG. 2ZZ shows a semiconductor structure 200zz including a semiconductor structure 202 formed from the semiconductor structure 200w. The semiconductor structure 202 can be formed by forming bit lines 222 in the semiconductor structure 200w. The bit lines 222 extend along the Y direction and can be formed in the dielectric layer 229. The bit lines 222 are in a second side of the semiconductor structure 202 opposite to the first side (e.g., as described with reference to FIG. 2W) along the Z direction. In other words, the second side is farther away from the semiconductor structure 204 than the first side along the Z direction. Each bit line 222 can be coupled to a corresponding channel structure 216. For example, the bit line 222 can be coupled to an end of the channel layer 216c of the channel structure 216 in the second side. A bit line contact structure (e.g., one that is similar to, or same as, the bit line contact structure 142 of FIG. 1B) can be formed in the semiconductor structure 202 to couple the bit line 222 to a corresponding bit line 220 in the first side. The corresponding bit line 220 is coupled to another end (e.g., the channel plug 216e) of the channel layer 216c of the channel structure 216 in the first side. The semiconductor structure 200zz can be an example of the semiconductor device 100 as illustrated in FIGS. 1A-1C. The semiconductor structure 202 of the semiconductor structure 200zz can be similar to, or same as the semiconductor structure 102 of the semiconductor device 100, and the semiconductor structure 204 of the semiconductor structure 200zz can be similar to, or same as the semiconductor structure 104 of the semiconductor device 100.

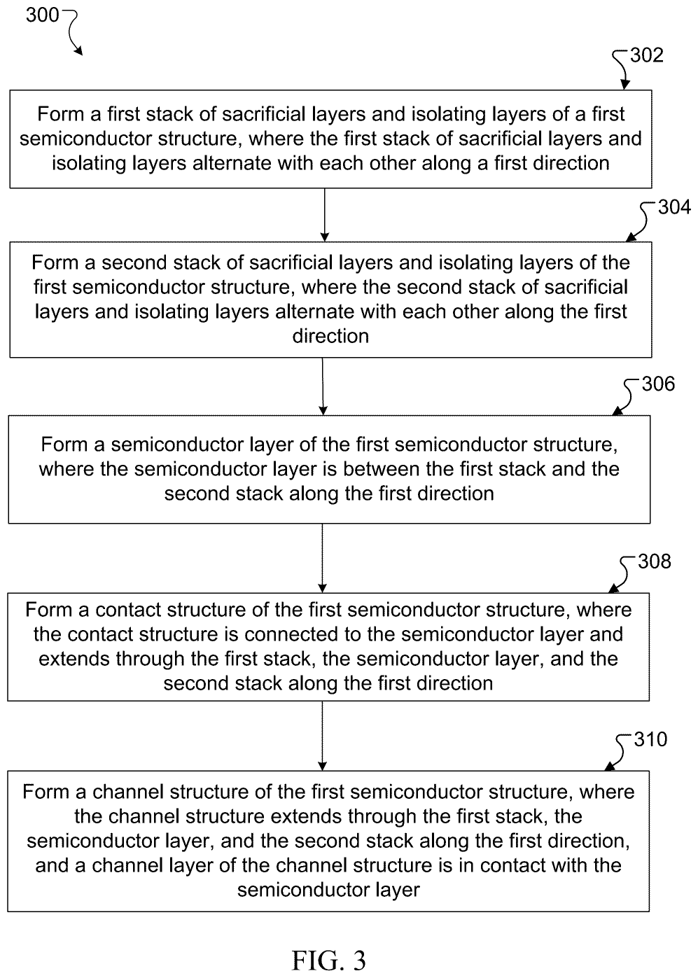

FIG. 3 illustrates a flow chart of an example process 300. The process 300 can be performed to form a semiconductor device (e.g., the semiconductor device 100 illustrated by FIGS. 1A-1C). The process 300 can be described in view of FIGS. 2A-2ZZ. The process 300 can include one or more steps of the fabrication process of forming the semiconductor structures in FIGS. 2A-2ZZ. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a first stack (e.g., the stack 208 of FIG. 2G) of sacrificial layers (e.g., the sacrificial layers 206D of FIG. 2G) and isolating layers (e.g., the isolating layers 206B of FIG. 2G) of a first semiconductor structure (e.g., the semiconductor structures 200g-200t of FIGS. 2G-2T) is formed. The first stack of sacrificial layers and isolating layers alternate with each other along a first direction (e.g., the Z direction).

At operation 304, a second stack (e.g., the stack 210 of FIG. 2G) of sacrificial layers (e.g., the sacrificial layers 206D of FIG. 2G) and isolating layers (e.g., the isolating layers 206B of FIG. 2G) of the first semiconductor structure (e.g., the semiconductor structures 200g-200t of FIGS. 2G-2T) is formed. The second stack of sacrificial layers and isolating layers alternate with each other along the first direction.

At operation 306, a semiconductor layer (e.g., the semiconductor layer 212 of FIG. 2T) of the first semiconductor structure is formed. The semiconductor layer is between the first stack and the second stack along the first direction.

At operation 308, a contact structure (e.g., the contact structure 214 of FIG. 2T) of the first semiconductor structure is formed. The contact structure is connected to the semiconductor layer and extends through the first stack, the semiconductor layer, and the second stack along the first direction.

At operation 310, a channel structure (e.g., the channel structure 216 of FIG. 2T) of the first semiconductor structure is formed. The channel structure extends through the first stack, the semiconductor layer, and the second stack along the first direction. A channel layer (e.g., the channel layer 216c of FIG. 2T) of the channel structure is in contact with the semiconductor layer.

In some implementations, forming the first stack includes forming a first deck (e.g., the deck 208a of FIG. 2A) of the first stack and a second deck (e.g., the deck 208b of FIG. 2D) of the first stack. Each of the first deck and the second deck includes one or more of the sacrificial layers and isolating layers in the first stack. Forming the contact structure includes forming a first segment (e.g., the contact hole 213-1 of FIG. 2B) of a contact hole extending through the first deck along the first direction and a second segment (e.g., the contact hole 213-2 of FIG. 2E) of the contact hole extending through the second deck along the first direction. Forming the channel structure includes forming a first segment (e.g., the channel hole 215-1 of FIG. 2B) of a channel hole extending through the first deck along the first direction and a second segment (e.g., the channel hole 215-2 of FIG. 2E) of the channel hole extending through the second deck along the first direction. The first segment of the channel hole and the first segment of the contact structure are formed by a first etching process (e.g., the first etching process described with reference to FIG. 2B). The second segment of the channel hole and the second segment of the contact structure are formed by a second etching process (e.g., the second etching process described with reference to FIG. 2E).

In some implementations, forming the semiconductor layer of the first semiconductor structure includes forming a first stop layer (e.g., the stop layer 212a of FIG. 2G), a sacrificial array common source (ACS) layer (e.g., the sacrificial ACS layer 211 of FIG. 2G), and a second stop layer (e.g., the stop layer 212b of FIG. 2G) on top of the first stack. The sacrificial ACS layer is between the first stop layer and the second stop layer along the first direction. Forming the second stack (e.g., the stack 210 of FIG. 2G) includes forming the second stack on top of the second stop layer (e.g., as described with reference to FIG. 2G).

In some implementations, forming the contact structure includes forming a third segment (e.g., the contact hole 213-3 of FIG. 2H) of the contact hole extending through the second stack, the second stop layer, the sacrificial ACS layer, and the first stop layer along the first direction. Forming the channel structure includes forming a third segment (e.g., the channel hole 215-3 of FIG. 2H) of the channel hole extending through the second stack, the second stop layer, the sacrificial ACS layer, and the first stop layer along the first direction. The third segment of the channel hole and the third segment of the contact structure are formed by a third etching process (e.g., the third etching process as described with reference to FIG. 2H).

In some implementations, forming the contact structure includes depositing a dielectric material and a conductive material into the contact hole (e.g., the contact hole 213 of FIGS. 2K-2N) to form a dielectric layer (e.g., the dielectric layer 221 of FIG. 2K) of the contact structure and a conductive layer (e.g., the conductive layer surrounded by the dielectric layer 221 as described with reference to FIG. 2K) of the contact structure, respectively. Forming the channel structure includes forming a channel layer (e.g., the channel layer 216c of FIG. 2Q) and a memory film (e.g., the memory film 216b of FIG. 2Q) in the channel hole (e.g., the channel hole 215 of FIG. 2Q). The memory film surrounds the channel layer.

In some implementations, forming the semiconductor layer of the first semiconductor structure includes: removing the sacrificial ACS layer to form a space (e.g., the space 223 of FIG. 2R); removing a portion of the memory film of the channel structure to expose a portion of the channel layer of the channel structure (e.g., as described with reference to FIG. 2S); removing a portion of the dielectric layer of the contact structure to expose a portion of the conductive layer of the contact structure (e.g., as described with reference to FIG. 2S); and depositing a semiconductive material (e.g., n-doped polysilicon as described with reference to FIG. 2T) into the space to form the semiconductive layer (e.g., as described with reference to FIG. 2T).

In some implementations, the process 300 further includes replacing (e.g., as described with reference to FIG. 2U) the sacrificial layers in the first stack and the sacrificial layers in the second stack with conductive layers (e.g., the conductive layers 206A of FIGS. 2U-2ZZ).

In some implementations, the process 300 further includes forming a first bit line (e.g., one of the bit lines 220 of FIG. 2W) and a first interconnect layer (e.g., the interconnect layer 236 of FIG. 2W) on a first side (e.g., the first side as described with reference to FIG. 2W) of the first semiconductor structure. The first interconnect layer is coupled to the channel structure and the contact structure. The first bit line extends along a second direction (e.g., the Y direction) perpendicular to the first direction and is coupled to a first end (e.g., the channel plug 216e of FIG. 2W) of the channel structure. The process 300 further includes forming a second semiconductor structure (e.g., the semiconductor structure 204 of FIG. 2X) including a control circuit (e.g., the peripheral circuits 228 of FIG. 2X) configured to control the channel structure of the first semiconductor structure and a second interconnect layer (e.g., the interconnect layer 238 of FIG. 2X). The process 300 further includes bonding (e.g., as described with reference to FIG. 2X) the first side of the first semiconductor structure to the second semiconductor structure through a bonding structure (e.g., the bonding structure 203 of FIG. 2X). The first interconnect layer is coupled to the second interconnect layer through the bonding structure.

In some implementations, the process 300 further includes forming a second bit line (e.g., one of the bit lines 222 of FIG. 2ZZ) extending along the second direction on a second side (e.g., the second side as described with reference to FIG. 2ZZ) of the first semiconductor structure and forming a bit line contact structure (e.g., the bit line contact structure as described with reference to FIG. 2ZZ) extending along the first direction. The bit line contact structure is coupled to the first bit line and the second bit line.

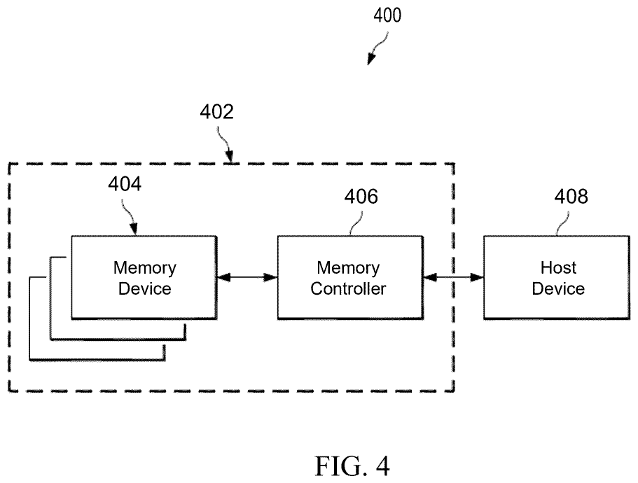

FIG. 4 illustrates a block diagram of an example system 400. The system 400 can have one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 4, the system 400 can include a host device 408 and a memory system 402 having one or more memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more memory devices 404.

A memory device 404 can be any memory device disclosed in the present disclosure, such as a memory device (e.g., a NAND Flash memory) as shown in FIGS. 1A-1C. Memory controller 406 (a.k.a., a controller circuit) is coupled to memory device 404 and host device 408. Consistent with implementations of the present disclosure, memory device 404 can include a plurality of conductive interconnections through a cover layer that are in contact with conductive pads in a conductive pad layer, and memory controller 406 can be coupled to memory device 404 through at least one of the plurality of conductive interconnections. Memory controller 406 is configured to control memory device 404. For example, memory controller 406 may be configured to operate a plurality of channel structures via word lines. Memory controller 406 can manage data stored in memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program (or write) operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising a first semiconductor structure, wherein the first semiconductor structure comprises:
a first stack of conductive layers and isolating layers alternating with each other along a first direction;
a second stack of conductive layers and isolating layers alternating with each other along the first direction;
a semiconductor layer between the first stack and the second stack along the first direction;
a contact structure connected to the semiconductor layer, wherein the contact structure extends through the first stack, the semiconductor layer, and the second stack along the first direction; and
a channel structure extending through the first stack, the semiconductor layer, and the second stack along the first direction, wherein the semiconductor layer is in contact with a channel layer of the channel structure.

2. The semiconductor device of claim 1, wherein the first stack comprises at least a first deck comprising one or more of the conductive layers and isolating layers in the first stack, and the contact structure comprises a first segment extending through the first deck along the first direction.

3. The semiconductor device of claim 2, wherein the first stack further comprises a second deck comprising one or more of the conductive layers and isolating layers in the first stack, and the contact structure further comprises a second segment extending through the second deck along the first direction and a third segment extending through the second stack.

4. The semiconductor device of claim 3, wherein the channel structure comprises a first segment, a second segment, and a third segment, the first segment of the channel structure extends through the first deck along the first direction, the second segment of the channel structure extends through the second deck along the first direction, and the third segment of the channel structure extends through the second stack along the first direction.

5. The semiconductor device of claim 2, wherein a quantity of the one or more conductive layers in the first deck is in a range between 3 to 10.

6. The semiconductor device of claim 1, further comprising a second semiconductor structure, wherein the second semiconductor structure is bonded to the first semiconductor structure along the first direction through a bonding structure, and the second semiconductor structure comprises a control circuit configured to control the channel structure of the first semiconductor structure.

7. The semiconductor device of claim 6, wherein the first semiconductor structure comprises a first interconnect layer coupled to the contact structure, and the first interconnect layer is coupled to the second semiconductor structure through the bonding structure.

8. The semiconductor device of claim 7, wherein the second semiconductor structure comprises a second interconnect layer coupled to the first interconnect layer through the bonding structure.

9. The semiconductor device of claim 6, wherein the channel structure comprises a first end coupled to a first bit line extending along a second direction perpendicular to the first direction and a second end coupled to a second bit line extending along the second direction, the first bit line is coupled to the control circuit of the second semiconductor structure, and the first bit line is coupled to the second bit line through a bit line contact structure extending along the first direction.

10. The semiconductor device of claim 1, wherein the contact structure comprises at least one of a metallic material, a polysilicon, or a titanium nitride (TiN).

11. A method, comprising:
forming a first stack of sacrificial layers and isolating layers of a first semiconductor structure, wherein the first stack of sacrificial layers and isolating layers alternate with each other along a first direction;
forming a second stack of sacrificial layers and isolating layers of the first semiconductor structure, wherein the second stack of sacrificial layers and isolating layers alternate with each other along the first direction;
forming a semiconductor layer of the first semiconductor structure, wherein the semiconductor layer is between the first stack and the second stack along the first direction;
forming a contact structure of the first semiconductor structure, wherein the contact structure is connected to the semiconductor layer and extends through the first stack, the semiconductor layer, and the second stack along the first direction; and
forming a channel structure of the first semiconductor structure, wherein the channel structure extends through the first stack, the semiconductor layer, and the second stack along the first direction, and a channel layer of the channel structure is in contact with the semiconductor layer.

12. The method of claim 11, wherein:
forming the first stack comprises forming a first deck of the first stack and a second deck of the first stack, each of the first deck and the second deck comprises one or more of the sacrificial layers and isolating layers in the first stack;
forming the contact structure comprises forming a first segment of a contact hole extending through the first deck along the first direction and a second segment of the contact hole extending through the second deck along the first direction; and
forming the channel structure comprises forming a first segment of a channel hole extending through the first deck along the first direction and a second segment of the channel hole extending through the second deck along the first direction, wherein the first segment of the channel hole and the first segment of the contact structure are formed by a first etching process, and the second segment of the channel hole and the second segment of the contact structure are formed by a second etching process.

13. The method of claim 12, wherein:
forming the semiconductor layer of the first semiconductor structure comprises forming a first stop layer, a sacrificial array common source (ACS) layer, and a second stop layer on top of the first stack, the sacrificial ACS layer being between the first stop layer and the second stop layer along the first direction; and
forming the second stack comprises forming the second stack on top of the second stop layer.

14. The method of claim 13, wherein:
forming the contact structure comprises forming a third segment of the contact hole extending through the second stack, the second stop layer, the sacrificial ACS layer, and the first stop layer along the first direction; and
forming the channel structure comprises forming a third segment of the channel hole extending through the second stack, the second stop layer, the sacrificial ACS layer, and the first stop layer along the first direction, wherein the third segment of the channel hole and the third segment of the contact structure are formed by a third etching process.

15. The method of claim 14, wherein:
forming the contact structure comprises depositing a dielectric material and a conductive material into the contact hole to form a dielectric layer of the contact structure and a conductive layer of the contact structure, respectively; and
forming the channel structure comprises forming a channel layer and a memory film in the channel hole, wherein the memory film surrounds the channel layer.

16. The method of claim 15, wherein forming the semiconductor layer of the first semiconductor structure comprises:
removing the sacrificial ACS layer to form a space;
removing a portion of the memory film of the channel structure to expose a portion of the channel layer of the channel structure;
removing a portion of the dielectric layer of the contact structure to expose a portion of the conductive layer of the contact structure; and
depositing a semiconductive material into the space to form the semiconductor layer.

17. The method of claim 16, further comprising:
replacing the sacrificial layers in the first stack and the sacrificial layers in the second stack with conductive layers.

18. The method of claim 17, further comprising:
forming a first bit line and a first interconnect layer on a first side of the first semiconductor structure, wherein the first interconnect layer is coupled to the channel structure and the contact structure, and the first bit line extends along a second direction perpendicular to the first direction and is coupled to a first end of the channel structure;
forming a second semiconductor structure comprising a control circuit configured to control the channel structure of the first semiconductor structure and a second interconnect layer; and
bonding the first side of the first semiconductor structure to the second semiconductor structure through a bonding structure, wherein the first interconnect layer is coupled to the second interconnect layer through the bonding structure.

19. The method of claim 18, further comprising:
forming a second bit line extending along the second direction on a second side of the first semiconductor structure; and
forming a bit line contact structure extending along the first direction, wherein the bit line contact structure is coupled to the first bit line and the second bit line.

20. A memory system, comprising:
a memory device comprising a first semiconductor structure; and
a memory controller coupled to the memory device and configured to control the memory device,
wherein the first semiconductor structure comprises:
a first stack of conductive layers and isolating layers alternating with each other along a first direction;
a second stack of conductive layers and isolating layers alternating with each other along the first direction;
a semiconductor layer between the first stack and the second stack along the first direction;
a contact structure connected to the semiconductor layer, wherein the contact structure extends through the first stack, the semiconductor layer, and the second stack along the first direction; and
a channel structure extending through the first stack, the semiconductor layer, and the second stack along the first direction, wherein the semiconductor layer is in contact with a channel layer of the channel structure.
